(19) United States
(12) Patent Application Publication
(10) Pub. No.: US 2024/0384394 A1
(43) Pub. Date: Nov. 21, 2024

(54) LOW CARBON DEFECT COPPER-MANGANESE SPUTTERING TARGET AND METHOD FOR PRODUCING THE SAME

(71) Applicant: Tosoh SMD, Inc., Grove City, OH (US)

(72) Inventors: Eduardo del Rio Perez, Dublin, OH (US); Erich Walter Theado, Columbus, OH (US); Lora Birkefeld Thrun, Grove City, OH (US)

(73) Assignee: Tosoh SMD, Inc., Grove City, OH (US)

(21) Appl. No.: 18/785,197

(22) Filed: Jul. 26, 2024

Related U.S. Application Data
(62) Division of application No. 18/120,358, filed on Mar. 10, 2023.
(60) Provisional application No. 63/318,775, filed on Mar. 10, 2022.

(51) Int. Cl. C23C 14/34; C22C 1/02; C22C 9/00; C22C 9/05; H01J 37/34

(52) U.S. Cl. CPC C23C 14/3414; C22C 9/00; C22C 9/05; H01J 37/3429; C22C 1/02

(57) ABSTRACT

Provided is a low carbon defect copper-manganese (CuMn) sputtering target and systems and methods for producing the same. The low carbon defect CuMn sputtering target may comprise of copper with a purity of at least about 99.9999%, manganese with a purity of about 99.9% to about 99.999%, and one or more active elements comprising of oxygen (O) at about 100 parts per million (ppm) to about 4000 ppm, iron (Fe) at about 5 parts per billion (ppb) to about 100 ppm, sulfur(S) at about 5 ppm to about 400 ppm, hydrogen (H) at about 1 ppm to about 10 ppm, and chromium (Cr) at about 5 ppb to about 200 ppm, wherein the manganese has a compositional range of up to about 5 wt %.

### CROSS REFERENCE TO RELATED APPLICATIONS

This application is a divisional of U.S. Utility application Ser. No. 18/120,358 filed on Mar. 10, 2023, entitled “Low Carbon Defect Copper-Manganese Sputtering Target and Method for Producing the Same” which claims priority to U.S. Provisional Patent Application No. 63/318,775, filed on Mar. 10, 2022, entitled “Low Carbon Defect Copper-Manganese Sputtering Target and Method for Producing the Same”, each of which are incorporated herein by reference in their entireties.

### TECHNICAL FIELD

This application relates to a low carbon defect copper-manganese sputtering target and method for producing the same and, more particularly, to a vacuum induction method for producing the low carbon defect copper-manganese sputtering target.

### BACKGROUND

The ongoing development to further shrink features in semiconductor integrated systems while improving performance required in the advanced 7 nm, 5 nm, 3 nm and beyond nodes require a reduction of defects generated during the thin film deposition process. Specifically, carbon-based defects, either as pure carbon and allotropes or as carbon-based compounds (e.g., carbides) encountered during the deposition in copper-manganese (CuMn) films cause detrimental performance, affecting the adhesion of the CuMn seed layer to the Tantalum Nitride/Tantalum (TaN/Ta) barrier. Since the development of the CuMn self-forming barrier and seed by Usui et al. (2005) and Nogami et al. (2010) for copper metal interconnects, semiconductor factories and chip designers adopted CuMn as the preferred alloy for seed layers prior to copper metallization in integrated circuits.

### SUMMARY

The following presents a summary of this disclosure to provide a basic understanding of some aspects. This summary is intended to neither identify key or critical elements nor define any limitations of embodiments or claims. This summary may provide a simplified overview of some aspects that may be described in greater detail in other portions of this disclosure. Furthermore, any of the described aspects may be isolated or combined with other described aspects without limitation to the same effect as if they had been described separately and in every possible combination explicitly.

In one aspect of the invention, a low carbon defect copper-manganese (CuMn) sputtering target is made of copper (Cu) with a purity of at least about 99.9999%; and an alloy addition. The alloy addition includes manganese (Mn) with a purity of about 99.9% to about 99.999%, with the manganese having a compositional range of up to about 5 wt %. The alloy addition also includes one or more active elements. The active elements include one or more of oxygen (O) at about 100 parts per million (ppm) to about 4000 ppm, iron (Fe) at about 5 parts per billion (ppb) to about 100 ppm, sulfur(S) at about 5 ppm to about 400 ppm, hydrogen (H) at about 1 ppm to about 10 ppm, and chromium (Cr) at about 5 ppb to about 200 ppm.

In another aspect of the invention, the low carbon defect CuMn sputtering target has a purity of at least about 99.999%.

In another aspect of the invention, the Cu and the alloy addition are charged into a crucible prior to melting the Cu, thereby forming a molten bath.

In another aspect of the invention, the alloy addition is added as a late addition by a dissolution device after the Cu has melted, the melted Cu forming a molten bath to which the alloy addition is added later.

In another aspect of the invention, the alloy addition is directionally dispensed by the dissolution device into a stirring wake of the molten bath in a crucible during a creation of a low carbon defect CuMn ingot used to form the sputtering target.

In another aspect of the invention, the dissolution device dispenses the alloy addition at a dissolution rate of about 17 grams/second (g/s) to about 167 g/s.

In another aspect of the invention, a resulting molten bath of the Cu and the alloy addition is homogenized for about 30 minutes (min) to about 120 min.

In yet another aspect, a method of forming a low carbon defect copper-manganese (CuMn) sputtering target includes, selecting raw material comprising of copper (Cu) with a purity of at least about 99.9999% and an alloy addition. The alloy addition including manganese (Mn) with a purity of about 99.9% to about 99.999%, and one or more active elements. The one or more active elements including one or more of oxygen (O) at about 100 parts per million (ppm) to about 4000 ppm, iron (Fe) at about 5 parts per billion (ppb) to about 100 ppm, sulfur(S) at about 5 ppm to about 400 ppm, hydrogen (H) at about 1 ppm to about 10 ppm, and chromium (Cr) at about 5 ppb to about 200 ppm, wherein the manganese has a compositional range of up to about 5 wt %. The method further including, melting the raw material into a molten alloy, casting the molten alloy into an ingot, thermomechanical processing the ingot into a target blank; and assembling the target blank into a sputtering target by joining the target blank onto a backing plate.

In another aspect of the invention, the method further includes charging the alloy addition and the Cu into a crucible.

In another aspect of the invention, the method further includes, adding the alloy addition as a late addition by a dissolution device into a molten Cu, thereby forming the molten alloy.

In another aspect of the invention, the method further includes, dispensing, by the dissolution device, the alloy addition into a stirring wake of the molten Cu.

In another aspect of the invention, the method further includes, dispensing of the alloy addition is at a dissolution rate of about 17 grams/second (g/s) to about 167 g/s.

In another aspect of the invention, the method further includes, homogenizing a resulting molten bath of the Cu and the alloy addition for about 30 minutes (min) to about 120 min.

In yet another aspect of the invention, a vacuum induction melting (VIM) furnace includes a controller and memory storing executable code when executed by the controller performs actions including, receiving predetermined parameters for the creation of a low carbon defect Cu-Mn ingot using an I/O device of the VIM furnace; pausing for a charging of raw material, the raw material comprising of copper (Cu) with a purity of at least about 99.9999% and an alloy addition, said alloy addition including manganese (Mn) with a purity of about 99.9% to about 99.999%, and one or more active elements. The one or more active elements including one or more of oxygen (O) at about 100 parts per million (ppm) to about 4000 ppm, iron (Fe) at about 5 parts per billion (ppb) to about 100 ppm, sulfur(S) at about 5 ppm to about 400 ppm, hydrogen (H) at about 1 ppm to about 10 ppm, and chromium (Cr) at about 5 ppb to about 200 ppm, wherein the manganese has a compositional range of up to about 5 wt %; pumping down a chamber of the VIM furnace using vacuum pump of the VIM furnace; melting the raw materials in a crucible using an induction coil and a temperature sensor of the VIM furnace, such that the raw materials in the crucible form a melt having a predetermined temperature value; maintaining the predetermined temperature value of the melt using the induction coil and temperature sensor until a predetermined soak time has elapsed; and casting an ingot by pouring the melt into a mold.

In another aspect of the invention, the code when executed by the controller performs additional actions including, charging the alloy addition and Cu into the crucible prior to pumping down the chamber of the VIM furnace.

In another aspect of the invention, the code when executed by the controller performs additional actions including, pumping down the chamber of the VIM furnace after the Cu is charged into the crucible and the alloy addition is charged into a dissolution device.

In another aspect of the invention, wherein the code when executed by the controller performs additional actions including, dispensing the alloy addition, using the dissolution device, into the crucible after the Cu has melted, wherein the alloy addition is directionally dispensed into a stirring wake of the melted Cu.

In another aspect of the invention, wherein the code when executed by the controller performs additional actions including, dispensing the alloy addition at a rate of about 17 grams/second (g/s) to about 167 g/s.

In another aspect of the invention, wherein the code when executed by the controller performs additional actions including, wherein the predetermined soak time value is about 30 minutes (min) to about 120 min.

According to an aspect of the embodiments disclosed herein, a low carbon defect copper-manganese (CuMn) sputtering target is provided. The low carbon defect CuMn sputtering target may comprise of copper (Cu) with a purity of at least about 99.9999% and an alloy addition. The alloy addition may comprise of manganese (Mn) with a purity of about 99.9% to about 99.999%, wherein the manganese has a compositional range of up to about 5 wt %, and one or more active elements, where the active elements include one or more of oxygen (O) at about 100 parts per million (ppm) to about 4000 ppm, iron (Fe) at about 5 parts per billion (ppb) to about 100 ppm, sulfur(S) at about 5 ppm to about 400 ppm, hydrogen (H) at about 1 ppm to about 10 ppm, and chromium (Cr) at about 5 ppb to about 200 ppm.

According to another aspect of the embodiments disclosed herein, a method of producing a CuMn sputtering target is provided. The method may comprise selecting raw material comprising of copper (Cu) with a purity of at least about 99.9999% and a combination of alloy addition comprising: manganese (Mn) with a purity of about 99.9% to about 99.999% and one or more active elements, the active elements including one or more of oxygen (O) at about 100 parts per million (ppm) to about 4000 ppm, iron (Fe) at about 5 parts per billion (ppb) to about 100 ppm, sulfur(S) at about 5 ppm to about 400 ppm, hydrogen (H) at about 1 ppm to about 10 ppm, and chromium (Cr) at about 5 ppb to about 200 ppm, wherein the manganese has a compositional range of up to about 5 wt %. The method may further comprise melting the raw material into a molten alloy, casting the molten alloy into an ingot, thermomechanical processing the ingot into a target blank, and assembling the target blank into a sputtering target by joining the target blank onto a backing plate.

According to another aspect of the embodiments disclosed herein, a system is provided. The system may comprise a processor coupled to a memory that stores processes executable by the processor. The processes may comprise determining whether a molten bath of copper (Cu) requires a late addition of alloy addition comprising manganese and one or more active elements. The processes may further comprise dispensing the alloy addition into the stirring wakes at a predetermined rate.

The following description and the drawings disclose various illustrative aspects. Some improvements and novel aspects may be expressly identified, while others may be apparent from the description and drawings.

### DESCRIPTION OF THE DRAWINGS

The accompanying drawings illustrate various systems, apparatuses, devices and methods in which like reference characters refer to like parts throughout, and in which:

FIG. 1 illustrates an example low carbon defect CuMn ingot transformed into a low carbon defect CuMn sputtering target in accordance with various disclosed aspects herein;

FIG. 2 is illustrates a vacuum induction melting furnace in accordance with various disclosed aspects herein;

FIG. 3 is a flow diagram of an embodiment of a method of forming a low carbon defect CuMn sputtering target in accordance with various disclosed aspects herein;

FIG. 4 is a flow diagram of an embodiment of a method of casting a low carbon defect copper-manganese (CuMn) ingot in accordance with various disclosed aspects herein;

FIG. 5 illustrates a dissolution device and the directional Mn alloying addition to the stirring wake;

FIG. 6 is a flow diagram of an example method of using a VIM to manufacture a low carbon defect copper-manganese (CuMn) ingot in accordance with various disclosed aspects herein;

FIG. 7 is a bar graph of the defect density comparison between the traditional VIM process and the VIM process disclosed herein; and

FIG. 8 is an ultrasonic scan visual comparison between the traditional VIM process and the VIM process disclosed herein.

The disclosed embodiments may be embodied in several forms without departing from its spirit or essential characteristics. The scope of the invention is defined in the appended claims, rather than in the specific description preceding them. All embodiments that fall within the meaning and range of equivalency of the claims are therefore intended to be embraced by the claims.

### DETAILED DESCRIPTION

Reference will now be made to exemplary embodiments, examples of which are illustrated in the accompanying drawings. It is to be understood that other embodiments may be utilized and structural and functional changes may be made. Moreover, features of the various embodiments may be combined or altered. As such, the following description is presented by way of illustration only and should not limit in any way the various alternatives and modifications that may be made to the illustrated embodiments. In this disclosure, numerous specific details provide a thorough understanding of the subject disclosure. It should be understood that aspects of this disclosure may be practiced with other embodiments not necessarily including all aspects described herein, etc.

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In at least some instances, the approximating language may correspond to the precision of an instrument for measuring the value. Range limitations may be combined and/or interchanged, and such ranges are identified and include all the sub-ranges stated herein unless context or language indicates otherwise. Other than in the operating examples or where otherwise indicated, all numbers or expressions referring to quantities of ingredients, reaction conditions and the like, used in the specification and the claims, are to be understood as modified in all instances by the term “about”.

“Optional” or “optionally” means that the subsequently described event or circumstance may or may not occur, or that the subsequently identified material may or may not be present, and that the description includes instances where the event or circumstance occurs or where the material is present, and instances where the event or circumstance does not occur or the material is not present.

As used herein, the terms “comprises”, “comprising”, “includes”, “including”, “has”, “having”, or any other variation thereof, are intended to cover a non-exclusive inclusion. For example, a process, method, article or apparatus that comprises a list of elements is not necessarily limited to only those elements, but may include other elements not expressly listed or inherent to such process, method, article, or apparatus.

The singular forms “a”, “an”, and “the” include plural referents unless the context clearly dictates otherwise.

A “processor”, as used herein, processes signals and performs general computing and arithmetic functions. Signals processed by the processor can include digital signals, data signals, computer instructions, processor instructions, messages, a bit, a bit stream, or other means that can be received, transmitted and/or detected. Generally, the processor can be a variety of various processors including multiple single and multicore processors and co-processors and other multiple single and multicore processor and co-processor architectures. The processor can include various modules to execute various functions.

A “memory”, as used herein can include volatile memory and/or nonvolatile memory. Non-volatile memory can include, for example, ROM (read only memory), PROM (programmable read only memory), EPROM (erasable PROM), and EEPROM (electrically erasable PROM). Volatile memory can include, for example, RAM (random access memory), synchronous RAM (SRAM), dynamic RAM (DRAM), synchronous DRAM (SDRAM), double data rate SDRAM (DDRSDRAM), and direct RAM bus RAM (DRRAM). The memory can also include a disk. The memory can store an operating system that controls or allocates resources of a computing device. The memory can also store data for use by the processor.

A “disk”, as used herein can be, for example, a magnetic disk drive, a solid state disk drive, a floppy disk drive, a tape drive, a Zip drive, a flash memory card, and/or a memory stick. Furthermore, the disk can be a CD-ROM (compact disk ROM), a CD recordable drive (CD-R drive), a CD rewritable drive (CD-RW drive), and/or a digital video ROM drive (DVD ROM). The disk can store an operating system and/or program that controls or allocates resources of a computing device.

Some portions of the detailed description that follows are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps (instructions) leading to a desired result. The steps are those requiring physical manipulations of physical quantities. Usually, though not necessarily, these quantities take the form of electrical, magnetic or optical non-transitory signals capable of being stored, transferred, combined, compared and otherwise manipulated. It is convenient at times, principally for reasons of common usage, to refer to these signals as bits, values, elements, symbols, characters, terms, numbers, or the like. Furthermore, it is also convenient at times, to refer to certain arrangements of steps requiring physical manipulations or transformation of physical quantities or representations of physical quantities as modules or code devices, without loss of generality.

However, all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or “determining” or the like, refer to the action and processes of a computer system, or similar electronic computing device (such as a specific computing machine), that manipulates and transforms data represented as physical (electronic) quantities within the computer system memories or registers or other such information storage, transmission or display devices.

Certain aspects of the embodiments described herein include process steps and instructions described herein in the form of an algorithm. It should be noted that the process steps and instructions of the embodiments could be embodied in software, firmware or hardware, and when embodied in software, could be downloaded to reside on and be operated from different platforms used by a variety of operating systems. The embodiments can also be in a computer program product which can be executed on a computing system.

The embodiments also relates to an apparatus for performing the operations herein. This apparatus can be specially constructed for the purposes, e.g., a specific computer, or it can comprise a general-purpose computer selectively activated or reconfigured by a computer program stored in the computer. Such a computer program can be stored in a non-transitory computer readable storage medium, such as, but is not limited to, any type of disk including floppy disks, optical disks, CD-ROMs, magnetic-optical disks, read-only memories (ROMs), random access memories (RAMs), EPROMS, EEPROMs, magnetic or optical cards, application specific integrated circuits (ASICs), or any type of media suitable for storing electronic instructions, and each electrically connected to a computer system bus. Furthermore, the computers referred to in the specification can include a single processor or can be architectures employing multiple processor designs for increased computing capability.

The algorithms and displays presented herein are not inherently related to any particular computer or other apparatus. Various general-purpose systems can also be used with programs in accordance with the teachings herein, or it can prove convenient to construct more specialized apparatus to perform the method steps. The structure for a variety of these systems will appear from the description below. In addition, the embodiments are not described with reference to any particular programming language. It will be appreciated that a variety of programming languages can be used to implement the teachings of the embodiments as described herein, and any references below to specific languages are provided for disclosure of enablement and best mode of the embodiments.

In addition, the language used in the specification has been principally selected for readability and instructional purposes, and may not have been selected to delineate or circumscribe the inventive subject matter. Accordingly, the disclosure of the embodiments is intended to be illustrative, but not limiting, of the scope of the embodiments, which is set forth in the claims.

Traditional copper (Cu) alloy manufacturing methods involve melting and casting ingots using processes such as vacuum induction melting (VIM), electron beam melting (EBM), cold crucible induction melting or induction skull melting (CCIM/ISM). However, EBM and CCIM/ISM suffer from excessive copper vaporization due to the low melting point of Cu at about 1084° C. and alloy microstructure and composition non-uniformities due to the high electrical and thermal conductivity of Cu. In as much, VIM is an ideal process to produce Cu and Cu alloys, more specifically CuMn, due to the ability to control the melting process by controlling the physical properties of the molten metal alloy (e.g., melting point and vapor pressure) and produce high quality ingots. However, VIM processes have inherited potential issues with defectivity generated from the melting process in the form of secondary phase particles assimilated during melting from ancillary refractory tooling. Refractory crucibles, molds, and insulation either by reaction or homogeneous nucleation drive the formation of defects capable of increasing the defectivity count in the produced ingot. Such defects can be transferred to the production of sputtering target and consequently generate defect during sputtering.

Therefore, there is a need to eliminate the defects generated from the melting process in the form of secondary phase particles from ancillary refractory tooling by reaction or homogenous nucleation. Additionally, there is a need to eliminate the defects caused by the reaction of Mn with graphite crucibles which results in Mn-based carbide compounds formed during the melting process and the carbon-based defects due to homogeneous nucleation at the refractory wall surface morphology of the graphite crucibles.

The embodiments disclosed herein provide a method to produce a low carbon defectivity copper-manganese (CuMn) sputtering target with a manganese (Mn) concentration up to about 5 wt % having a purity of about 99.999% or higher. Disclosed herein is a method to melt and cast high volume CuMn alloys utilizing vacuum induction melting (VIM) capable of producing a low defect sputtering target with improved performance in comparison with traditional VIM melting/casting process. The process begins with a chemical selection of the Cu raw material, Mn raw material and an active elements combination which includes certain elements capable of producing the overall metal purity range desired for the alloy, maintain the required compositional range of up to about 5 wt % Mn, while producing the desired active defect reduction.

The Cu raw material range require the overall purity to be at least about 99.9999%. The Mn raw material range require the overall purity to be about 99.9% to 99.999% (5) with the following active elements in these specific ranges: oxygen (O) a minimum of about 100 parts per million (ppm) to a maximum of about 4000 ppm, iron (Fe) a minimum of about 5 parts per billion (ppb) to a maximum of about 100 ppm, sulfur(S) a minimum of about 5 ppm to a maximum of about 400 ppm, hydrogen (H) a minimum of about 1 ppm to a maximum of about 10 ppm, and chromium (Cr) a minimum of about 5 ppb to a maximum of about 200 ppm. These elements, alone and/or in combination, act as carbon getters to form evaporable gaseous forms of COₓ from the melt during the casting process. The Mn and one or more of the active elements (e.g., carbon getters) may be added as a late addition after the Cu has been charged and melted. The Mn and the active elements may be added as a powder, flake, sponge, chunks, ingot, or a combination thereof. The active role of these elements (e.g., carbon getters) was proven with the reduction of defects in sputtering targets. The Mn and one or more of the active elements may be added as an alloy addition charged in the crucible along with the Cu raw material. The alloy addition may also be added to the crucible later as a late addition.

The disclosed VIM method is an improvement over the traditional VIM process by enabling the utilization of known refractory ancillary equipment like graphite, magnesium oxide (MgO), aluminum oxide (Al₂O₃, zirconium dioxide (ZrO₂) as well as refractory metals like tantalum (Ta), tungsten (W), and molybdenum (Mo). Refractory ancillary equipment, refractory metals, and refractory tools made of graphite is the preferred embodiment as carbon getters are utilized to remove carbon-based defects. However, the embodiments disclosed herein is designed to eliminate defects caused by reaction of the late alloy addition with the crucible walls so that other types of refractory ancillary equipment, refractory metals, and refractory tools may also be used. This method eliminates the potential generation of defects caused by the reaction of the alloying Mn with the crucible walls or by physical breakdown of crucible material with the melt. Specifically, the reaction of Mn with graphite crucibles results in Mn-based carbide compounds formed during melting and carbon-based defects due to homogeneous nucleation at the refractory wall surface morphology of graphite crucibles. This improved process employs a custom-designed Programmable Logic Controller (PLC) controlled process, and a device that maintains a time-based Mn alloying addition defined for each alloy composition. The alloying addition comprises of Mn and an active element or a combination of the active elements (e.g., carbon getters). The PLC-controlled Mn alloying directionality inserts the alloying addition away from the crucible wall and into the one or more electromagnetically induced “stirring wakes” generated by the VIM process. The one or more stirring wakes are induced away from the crucible wall and towards the center of the crucible, such that they are not located by the crucible wall. This keeps the Mn away from the crucible wall, thereby preventing the introduction of carbide impurities by the Mn contacting the crucible wall. The PLC program, alloying addition, and dispersion device are synchronously tuned to produce a uniform dissolution of alloy addition with a predetermined dispensing rate between about 17 to about 167 gram/second (g/s). Stated alternatively, the PLC program, using the dispersion device, introduces the alloying addition into the stirring wakes of the melt at a predetermined rate of about 17 to about 167 grams/second (g/s).

The disclosed VIM method produces a measurable improvement in defect levels of about 50% or greater in comparison with traditional VIM process. This improvement is evaluated utilizing ultrasonic defect inspection described in U.S. Pat. No. 6,739,196 B2.

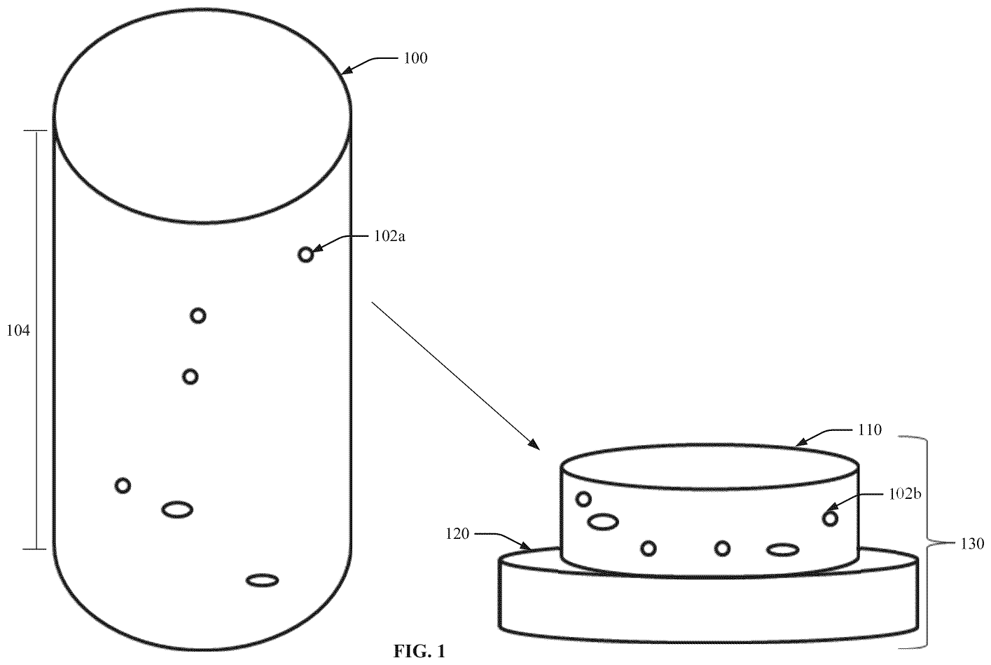

Turning to FIG. 1, which illustrates a low carbon defect CuMn sputtering target 130 (e.g., sputtering target 130) that may be produced by the methods disclosed herein to achieve low carbon defectivity as compared to the traditional VIM process. The disclosed methods may comprise selecting raw materials to melt and cast utilizing a VIM process that employs a Programmable Logic Controller (PLC) process to add the alloy addition at a predetermined rate and position. The raw material may comprise of Cu and an alloy comprising of Mn and an active element or a combination of active elements (e.g., carbon getters) such as, one or more of, O, Fe, S, H, and Cr.

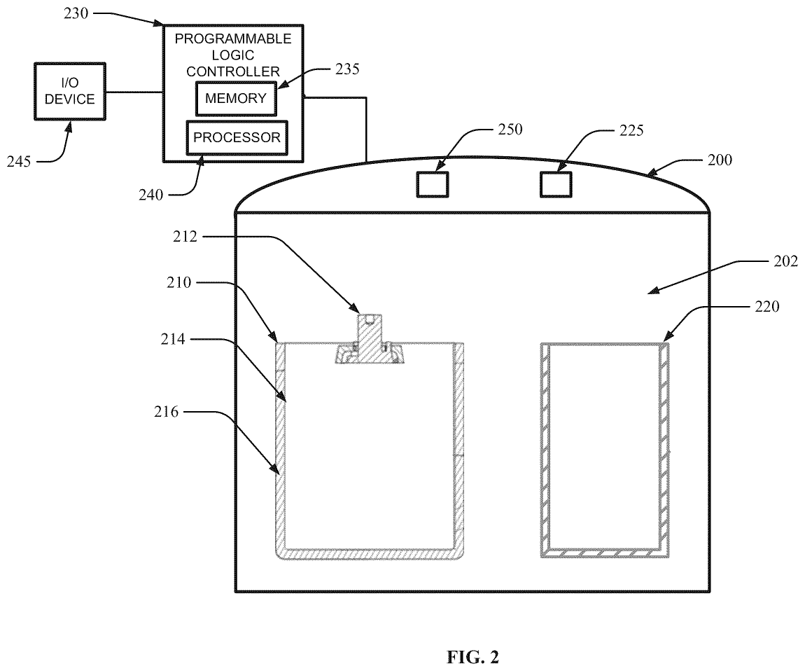

The VIM process may begin with charging the Cu into a crucible 210 located inside a chamber 202 of a VIM furnace 200, as shown in FIG. 2. The chamber 202 may be closed and processing parameters for the VIM furnace 200 such as chamber pressure value, melt temperature value, and soak time value may be set for the casting process. Setting the chamber pressure value allows air to be removed from the chamber 202 using vacuum pump 225. The chamber pressure value may range from about 0 torr (vacuum in Table I below) to about 500 torr. The temperature value of the melt in the crucible 210 of the VIM furnace 200 may set at about 1100° C. to about 1400° C. A soak time of about 20 minutes (min) to about 120 min may be set to let the molten metal or molten metal alloy homogenize.

The alloy addition may be charged into the crucible along with the raw Cu material or the alloy addition may be later as a late addition, such as by using dissolution device 212. A dissolution device 212 may be operatively positioned above the crucible 210 for dispensing the alloy addition into the crucible 210. The dissolution device 212 may be controlled by the PLC process to dispense the alloy addition into the molten metal of melted Cu to achieve a predetermined dissolution (dispensing) rate of about 17 grams/second (g/s) to about 167 g/s and direct the insertion of the alloy addition away from a crucible wall 214. The alloy addition may be added to the dissolution device 212 during setup (e.g., charging the crucible 210 with raw materials and setting the processing parameters) for automatic dispensing if it is determined that a late addition is required. The molten bath comprising of Cu, Mn, and a carbon getter or a combination of carbon getters (e.g., active elements) may be homogenized (e.g., soaked) for a predetermined period of time (e.g., soak time, hold time, etc.). After the molten bath (melt) has soaked for a predetermined length of time at the predetermined temperature, the molten bath (melt) may be poured into a mold 220 to cast an ingot 100, as illustrated in FIG. 1.

The ingot 100 as produced by the method disclosed herein may have fewer defects 102a compared to the traditional VIM process, and thus, the resulting sputtering target 130 may also have fewer defects 102b. The amount (e.g. number and severity) of defects in the ingot 100 determines the amount of defects in the sputtering target 130, since the ingot 100 is formed into the sputtering target 130. Therefore, decreasing the amount of defects 102a in the ingot 100 also decreases the amount of defects 102b in the resulting sputtering target 130.

The ingot 100 may be thermomechanically processed and assembled into the sputtering target 130. The thermomechanical processing may compress the ingot 100 along a dimension 104 to form a disc-shaped target blank 110. The defects 102a from the ingot 100 are retained in the target blank 110 as defects 102b. The target blank 110 may be joined to a backing plate 120 to produce sputtering target 130, which also retains the defects 102b. For this reason, the selection of the raw material and the casting process of the ingot 100 may be essential for the quality of the sputtering target 130. The ingot 100, and therefore the sputtering target 130 as well, should be composed of a CuMn metal alloy comprising of Mn at a concentration of up to about 5 wt % with an overall CuMn metal alloy purity of about 99.999% or higher.

The VIM furnace 200 also includes induction coil 216 for heating the melt within crucible 210 and creating stirring wakes within the melt. VIM furnace 200 also includes a temperature sensor 250 for monitoring the temperature of the melt within crucible 210. VIM furnace 200 also includes a PLC 230 having a memory 235 and a processor 240. A user enters parameter values for the VIM furnace 200 using the I/O device 245 that interfaces with the PLC. The I/O device 245 also permits a user to monitor the status of the VIM furnace 200. The parameter values are stored in the memory of PLC 230 and executed by processor 240 of PLC 230. The parameters and parameter values may include those listed below in Table I. Stated alternatively, the parameter values stored in the memory 235 of PLC 230 may include, but are not limited to, chamber pressure, allot addition method, temperature, and soak time, as well as whether the dissolution device 212 will be used to add the alloy additions (e.g. whether there will be late additions), and the dispensing (dispersion rate) of the dissolution device 212 when used.

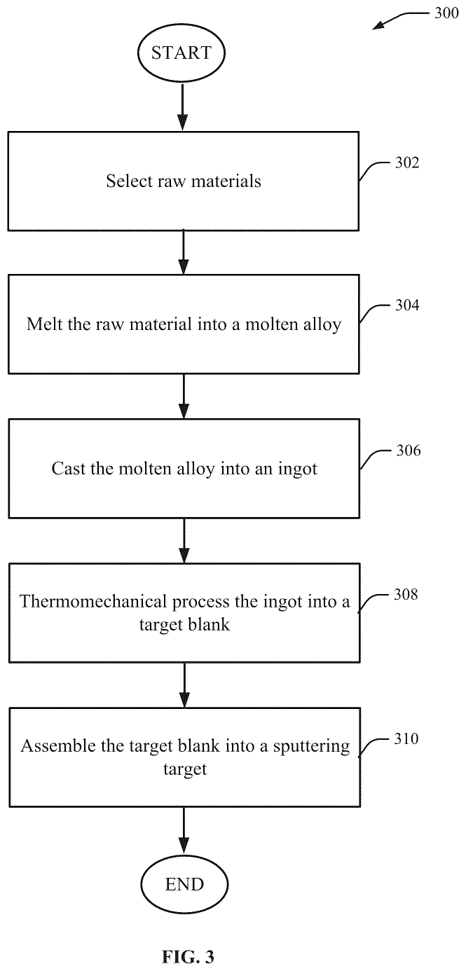

With reference to FIG. 3, an exemplary method 300 is provided for producing the low carbon defect sputtering target 130. At step 302, the method 300 may comprise of selecting raw materials. The raw material may comprise of Cu and an alloy addition. The Cu raw material require a purity range of at least about 99.9999%. The alloy addition may comprise of Mn and a reactive element or a combination of reactive elements, which acts as carbon getters that forms evaporable gaseous forms of COₓ from the melt during the casting process. The Mn may have a compositional range of up to about 5 wt % with a purity of about 99.9% to 99.999%. The active elements (e.g., carbon getters) may comprise of either O a minimum of about 100 parts per million (ppm) to a maximum of about 4000 ppm, Fe a minimum of about 5 ppb to a maximum of about 100 ppm, S a minimum of about 5 ppm to a maximum of about 400 ppm, H a minimum of about 1 ppm to a maximum of about 10 ppm, or Cr a minimum of about 5 ppb to a maximum of about 200 ppm, or a combination thereof. The Mn and these active elements (e.g., carbon getters) may come in various forms such as, but not limited to powder, flake, sponge, chunks, and ingot.

At step 304, the method 300 may comprise of melting the selected raw material. The Cu may be charged into the crucible 210 and melted at a predetermined temperature. The alloy addition of Mn and an active element or a combination of active elements (e.g., one or more carbon getters) may be added as an alloy addition to form a homogenized molten bath of molten alloy. The alloy addition may charged into the crucible 210 along with the Cu raw material, or alternatively, the alloy addition may be added to the dissolution device 212 for automatic dispensing of the alloy addition at a later time as a late addition. The dissolution device 212 may programmed to dispense the alloy addition into the crucible 210 away from the crucible wall 214 at a predetermined rate of about 17 g/s to about 167 g/s. Once the molten bath (melt) of raw material (Cu and alloy addition) reaches the predetermined temperature, the melt is permitted to soak for a predetermined length of time. In embodiments where the dissolution device 212 is used, the molten bath is permitted to reach the predetermined temperature prior to the dissolution device 212 dispersing the alloy addition into the molten bath (Cu melt). The dissolution device is controlled by the PLC 230 and directionally dispenses the alloy addition in a direction away from the crucible wall 214, such as into a stirring wake of the molten bath. Stated alternatively, the molten bath may be homogenized (e.g., soak) for a predetermined length of time (e.g. about 20 min to about 120 min) prior to casting the molten allot into the ingot 100.

At step 306, the method 300 may comprise of casting the molten alloy into the ingot 100 once the soak time of the molten alloy has elapsed. At step 308, the method 300 may comprise of thermomechanical processing the ingot 100 into the target blank 110 whereby the ingot 100 may be compressed along the dimension 104 into a disc shape. At step 310, the method 300 may comprise of assembling the target blank 100 into the sputtering target 130 by joining the target blank 110 to the backing plate 120. The resulting sputtering target 130 may be a low carbon defect CuMn sputtering target with a compositional range of up to about 5 wt % Mn and an overall purity of about 99.999% or higher.

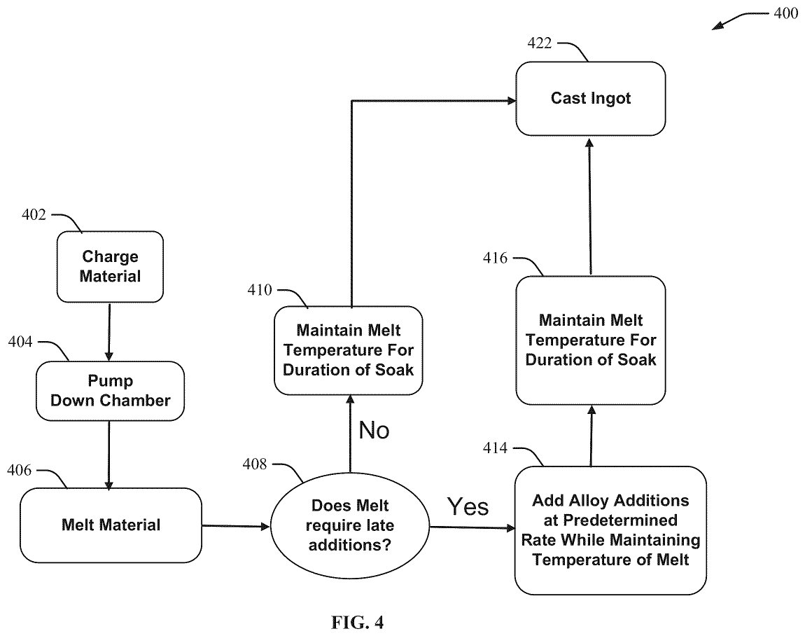

FIG. 4 further illustrates an example casting process 400 to cast the selected raw materials into the ingot 100. The selected raw materials may comprise of Cu having an overall purity of at least about 99.9999% and an alloy addition comprising of Mn with a concentration up to about 5 wt % (e.g., compositional range of up to about 5 wt %) having an overall purity of about 99.9% to about 99.999% and one or more active elements (e.g., carbon getters) comprising of O at a minimum of about 100 ppm to a maximum of about 4000 ppm, Fe at a minimum of about 5 ppb to a maximum of about 100 ppm, S at a minimum of about 5 ppm to about a maximum of about 400 ppm, H at a minimum of about 1 ppm to a maximum of about 10 ppm, or Cr at a minimum of about 5 ppb to a maximum of about 200 ppm. Thus, the ingot 100 will have an Mn content between about 0 wt %-about 5 wt %.

At step 402, the casting process 400 may comprise of charging the selected raw material of Cu into the crucible 210. The crucible 210 may be wrapped with induction coil 216, which is positioned to induce 200 stirring wakes directed away from the crucible walls 214. At this point, in an example preferred embodiment, the alloy addition (e.g., late addition) may be placed in the dissolution device 212 for inclusion as a late addition into the melt, and the predetermined processing parameters may be set. In other embodiments, the alloy addition may be charged into the crucible 210 along with the raw Cu material and the processing parameters may be set. Table I further depicts the processing parameters for a preferred embodiment and additional embodiments Alt A-E (e.g., Alternative A-E). These processing parameters may be entered into the PLC 230 using the I/O device 245, stored in the memory 235 of the PLC, and executed using the processor 240 of the PLC. It is contemplated that the PLC 230 may be any suitable controller.

TABLE I
Processing Parameters

| | | Alloy | | Soak |
|---|---|---|---|---|
| | Pressure | Addition | Temperature | Time |
| Conditions | (Torr) | Method | (C.) | (Min) |
| Preferred | 50-300 | Late addition | 1250 +/− 100 | 30-60 |
| Alt A | 100-500 | Late addition | 1250 +/− 150 | 20-120 |
| Alt B | Vacuum | Late addition | 1250 +/− 150 | 20-120 |
| Alt C | 50-300 | Charged | 1250 +/− 150 | 20-120 |
| | | crucible | | |
| Alt D | 100-500 | Charged | 1250 +/− 150 | 20-120 |
| | | crucible | | |
| Alt E | Vacuum | Charged | 1250 +/− 150 | 20-120 |
| | | crucible | | |

For example, in a preferred embodiment, the vacuum level of the chamber 202 may be about 50 torr to about 300 torr, the method of alloy addition may be a late addition (e.g., added later via the dissolution device 212), the temperature for the melt may be about 1150° C. to about 1350° C., and the soak time (e.g., hold time) may be about 30 min to 60 min. In an another embodiment, Alt A (e.g., Alternative A), the vacuum level of the chamber 202 may be about 100 torr to about 500 torr, the method of alloy addition may be a late addition (e.g., added later via the dissolution device 212), the temperature for the melt may be about 1100°° C. to about 1400° C., and the soak time (e.g., hold time) may be about 20 min to about 120 min. In an another embodiment, Alt B (e.g., Alternative B), the vacuum level of the chamber 202 may be a vacuum (e.g., about 0 torr), the method of alloy addition may be a late addition (e.g., added later via the dissolution device 212), the temperature for the melt may be about 1100° C. to about 1400° C., and the soak time (e.g., hold time) may be about 20 min to about 120 min. In an another embodiment, Alt C (e.g., Alternative C), the vacuum level of the chamber 202 may be about 50 torr to about 300 torr, the method of alloy addition may be charged crucible (e.g., charged into the crucible 210 with the raw Cu material at step 402), the temperature of the melt may be about 1100° C. to about 1400° C., and the soak time (e.g., hold time) may be about 20 min to about 120min. In an another embodiment, Alt D (e.g., Alternative D), the vacuum level of the chamber 202 may be about 100 torr to about 500 torr, the method of alloy addition may be charged crucible (e.g., charged into the crucible 210 with the raw Cu material at step 402), the temperature for the melt may be about 1100° C. to about 1400° C., and the soak time (e.g., hold time) may be about 20 min to about 120 min. In an another embodiment, Alt E (e.g., Alternative E), the vacuum level of the chamber 202 may be a vacuum (e.g., about 0 torr), the method of alloy addition may be late addition (e.g., added later via the dissolution device 212), the temperature for the melt may be about 1100° C. to about 1400° C., and the soak time (e.g., hold time) may be about 20 min to about 120 min.

At step 404, the casting process 400 may comprise pumping down the chamber 210, to remove air, to achieve a predetermined pressure within chamber 210 as described in Table I. The pumping down of the chamber 210 may be controlled by the PLC and a vacuum pump 225 of the VIM furnace 200.

At step 406, the casting process 400 may comprise melting the raw material charged into the crucible 210. The temperature for the melt is described in the processing parameters in Table I. If the alloy addition method is a late addition, there is no alloy addition yet and only copper is contained in the melt. If the alloy addition method is not a late addition (e.g., a charged crucible alloy addition method), the alloy addition is already charged into the crucible 210 and the raw metallic material in the melt includes both the Cu and alloy addition. The raw metallic material may be melted through the induction of eddy currents which leads to resistive heating of the raw metallic metals and stirring wakes inside the crucible 210 within the induction coil 216. The stirring wakes are directed away from the crucible walls 214.

At step 408, the casting process 400 may comprise determining whether the melt require late additions, e.g., whether the alloy addition method of the processing parameters as shown in Table I is a late addition (e.g., the alloy addition is placed in the dissolution device 212 to be alloyed later as a late addition) or a charged crucible (e.g., the alloy addition is charged into the crucible along with the raw Cu material). If late additions are not required in step 408, the casting process 400 may proceed to step 410. If late additions are required in step 408, the casting process may proceed to step 414.

At step 410, temperature of the melt is maintained at the predetermined temperature value for the predetermined soak time value, such as those shown in Table I, during which time the melt homogenizes. In an embodiment, the predetermined soak time may range between about 20 min-about 120 min. At step 412, the casting process 400 may include adjusting a current value of the induction coil 216 to maintain the predetermined temperature value of the melt for the predetermined soak time value. The casting process 400 proceeds to step 422 once the predetermined soak time value has elapsed.

At step 414, the casting process 400 may comprise adding material (e.g., alloy addition) at a predetermined rate to the melt. The dissolution device 212 may controlled by the PLC to add (e.g., dispense) the alloy addition into the melt contained in the crucible 210 at a predetermined rate of about 17 g/s to about 167 g/s. The dissolution device 212 may also be controlled to add the alloy addition into the crucible 210 away from the crucible wall 214. During step 414, the temperature of the melt in the crucible 210 is maintained by the PLC 230 using the induction coil 216 and melt temperature sensor 250.

At step 416, the casting process 400 may comprise maintaining the temperature of the melt (molten bath) at the predetermined temperature value for the predetermined soak time value, such as those described in Table I. For example, in a preferred embodiment, the molten bath may be soaked for about 30 min-about 60 min. In other embodiments, the molten bath may be soaked for about 20 min-about 120 min. This soak time may be described as a hold time to allow the molten bath to homogenize. During the soak time, the casting process 400 may include measuring the temperature value of the melt using a suitable measuring device and adjusting a current value of the induction coil 216, using the PLC 230, to maintain the predetermined temperature value of the melt throughout the predetermined soak time (e.g. until the predetermined soak time has elapsed). The casting process 400 proceeds to step 422 once the predetermined soak time value has elapsed.

At step 422, the casting process 400 may comprise casting the ingot 100. The melt, a molten alloy comprising of Cu and alloy addition, may be poured from the crucible 210 into the mold 220 to cast the ingot 100. The ingot 100 casted using the casting process 400 may be a low carbon defect CuMn ingot with an Mn concentration up to about 5 wt % having a purity of about 99.999% or higher. The PLC 230 may control the casting process (e.g. pouring of the melt from the crucible 210 into the mold 220).

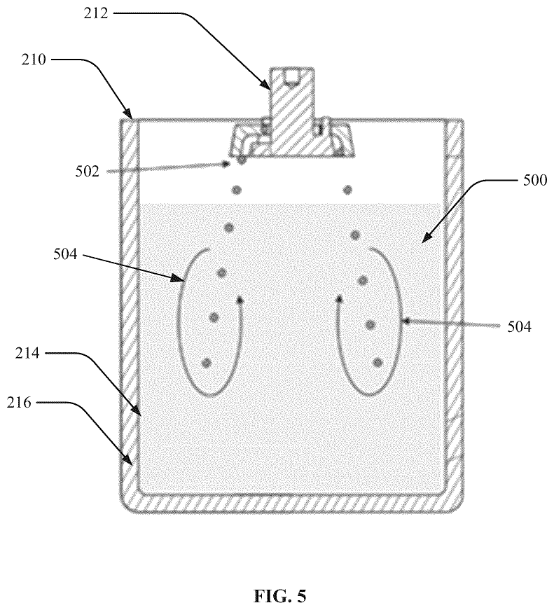

FIG. 5 further illustrates the dissolution of the alloy addition (e.g., dissolution process) by the dissolution device 212. FIG. 5 illustrates the dissolution device 212 and the direction at which the alloy addition 502 (e.g., a late addition) is inserted into the electromagnetic stirring wakes 504 of the molten bath 500. The disclosed dissolution process enables the utilization of known refractory ancillary equipment, refractory metals, and refractory tools such as graphite, MgO, Al₂O₃, ZrO₂, Ta, W, and Mo. However, graphite is preferred, and other ceramic type of crucible is nonconductive and can create inclusion contamination in the melt that are nonconductive that can create arcing. More specifically, the dissolution device 212 may dispense the alloy addition 502 away from the crucible wall 214 and into the electromagnetically induced stirring wakes 504 (e.g., stirring wakes 504) imparted by the induction coil 216. The dissolution device 212 may be centrally located over the crucible 210, which is wrapped with the induction coil 216. The dissolution device 212 may be controlled by programmable logic controlled (PLC) 230 to dispense (e.g., disperse or discharge) the alloy addition 502 into the stirring wakes 504 of the molten bath 500, away from the crucible wall 214, at a predetermined dissolution rate of about 17 g/s to about 167 g/s.

The alloy addition 502 (e.g., a late addition) may comprise of Mn with a concentration up to about 5 wt % (e.g., compositional range up to about 5 wt %) having an overall purity of about 99.9% to about 99.999% and one or more active elements (e.g., carbon getters). The active elements can include O at a minimum of about 100 ppm to a maximum of about 4000 ppm, Fe at a minimum of about 5 ppb to a maximum of about 100 ppm, S at a minimum of about 5 ppm to about a maximum of about 400 ppm, H at a minimum of about 1 ppm to a maximum of about 10 ppm, or Cr at a minimum of about 5 ppb to a maximum of about 200 ppm. The alloy addition 502 may comprise of one or more active elements or the alloy addition may comprise all of these active elements at the range described. The alloy addition may be a powder, flake, sponge, chunks, ingot, or a combination thereof.

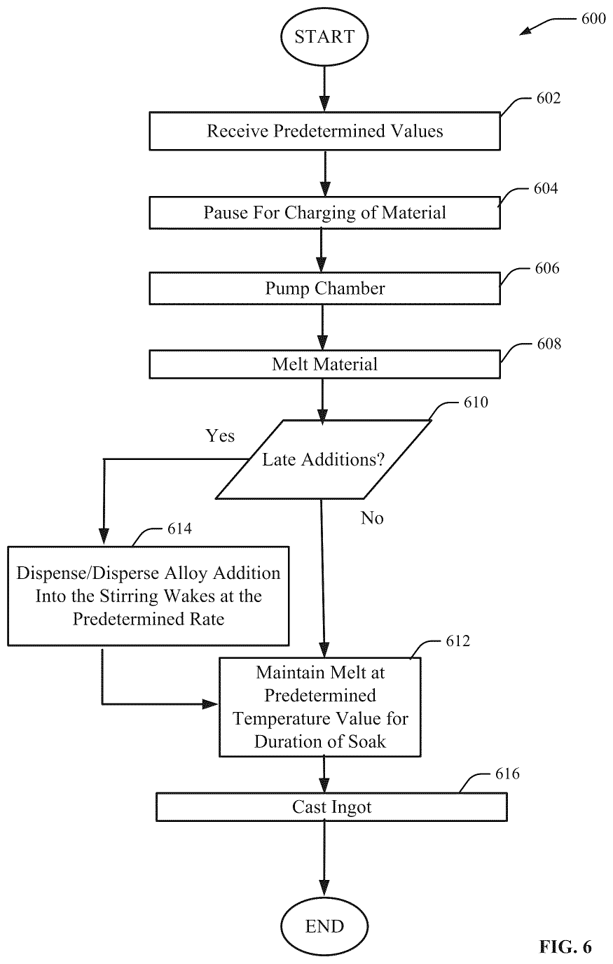

FIG. 6 is a program for PLC 230 to create a low carbon defect Cu-Mn ingot 100 using selected raw materials. The ingot is then formed into a low carbon defect Cu-Mn sputtering target blank 110 that is attached to a backing plate 120 to form a low carbon defect Cu-Mn sputtering target 130. Further, since PLC 230 includes a processor 240 and memory 235, the term PLC 230 is intended to encompass embodiments of VIM furnace 200 that are implemented with processor 240 and memory 235. The program of FIG. 6 is stored in memory 235 and executed by processor 240 and directed to a method for creating a low carbon defect Cu-Mn ingot 100 for use in forming a low carbon defect Cu-Mn sputtering target 130.

In step 602 the VIM furnace 200 receives predetermined values for parameters using the I/O device 245 of PLC 230. The predetermined parameter values are stored in memory 235. The parameters and predetermined parameter values may include those listed below in Table I. Stated alternatively, the predetermined parameter values stored in the memory 235 of PLC 230 may include, but are not limited to, chamber pressure, allot addition method, temperature, and soak time, as well as whether the dissolution device 212 will be used to add the alloy additions (e.g. whether there will be late additions), and the dispensing (dispersion rate) of the dissolution device 212 when used. In an exemplary embodiment, the dispending rate of the dissolution device 212 may between about 17 g/s to about 167 g/s.

Once the predetermined parameter values are stored in memory 235, the program proceeds to step 604 where the program pauses for the charging of raw material in the crucible 210. The raw material includes Cu placed in the crucible 210. The raw materials also includes alloy additions, which may also be placed in the crucible 210 or the dissolution device 212, in accordance with the predetermined parameter value for late additions.

In 606 the chamber 202 is pumped down to the predetermined chamber pressure value using the vacuum pump 225.

In 608, the raw materials in the crucible 210 are melted using the induction coil 216 and temperature sensor 250, such that the melt achieves a predetermined temperature value.

In 610, the late additions parameter value is examined. If the late additions parameter is set to “NO”, then the program proceeds to 612, where the temperature value of the melt in the crucible 210 is maintained at the predetermined temperature value, using the induction coil 216 and temperature sensor 250, until a predetermined soak time value has elapsed.

In the late additions parameter is set to “YES”, then the programs proceeds to 614, where alloy additions are dispensed into the stirring wakes 504 of the melt in the crucible 210 using the dissolution device 212 as a predetermined rate until all of the alloy additions in the dissolution device 212 have been dispensed. The alloy additions are directed toward the stirring wakes 504 and away from the crucible walls 214. Once the allow additions have been added to the melt, the program proceeds to step 612.

After the predetermined sock time value has elapsed in step 612, the program proceeds to step 616 where the ingot is cast by pouring the melt from the crucible 210 into the mold 220. In some embodiments, the PLC 230 may direct a mechanism attached to the crucible to pour the melt from the crucible 210 into the mold 220.

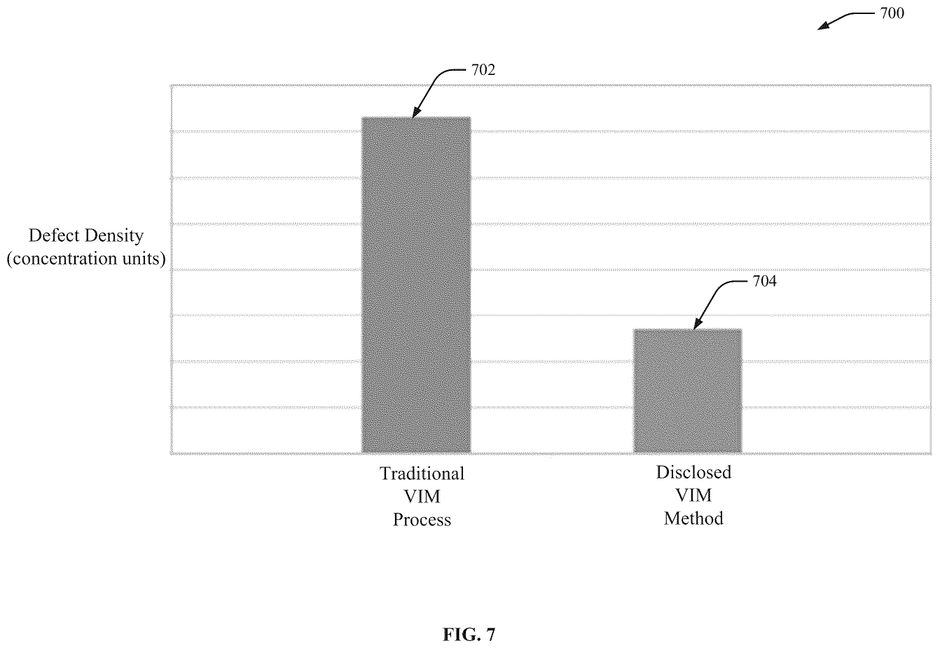

Referring now to FIG. 7, which illustrates a bar graph 700 comparing the defect density in concentration units of sputtering targets made using the traditional VIM process and sputtering targets (e.g., sputtering target 130) made using the herein disclosed VIM method, which comprise of the selection of raw material and the casting process (e.g., casting process 400). The bar 702 represents the traditional VIM process and the bar 704 represents the herein disclosed VIM method. The defects is measured by concentration units, and as illustrated, for every 2+defects in the sputtering targets made using the disclosed VIM method there are 7+defects in the sputtering targets using the traditional VIM process.

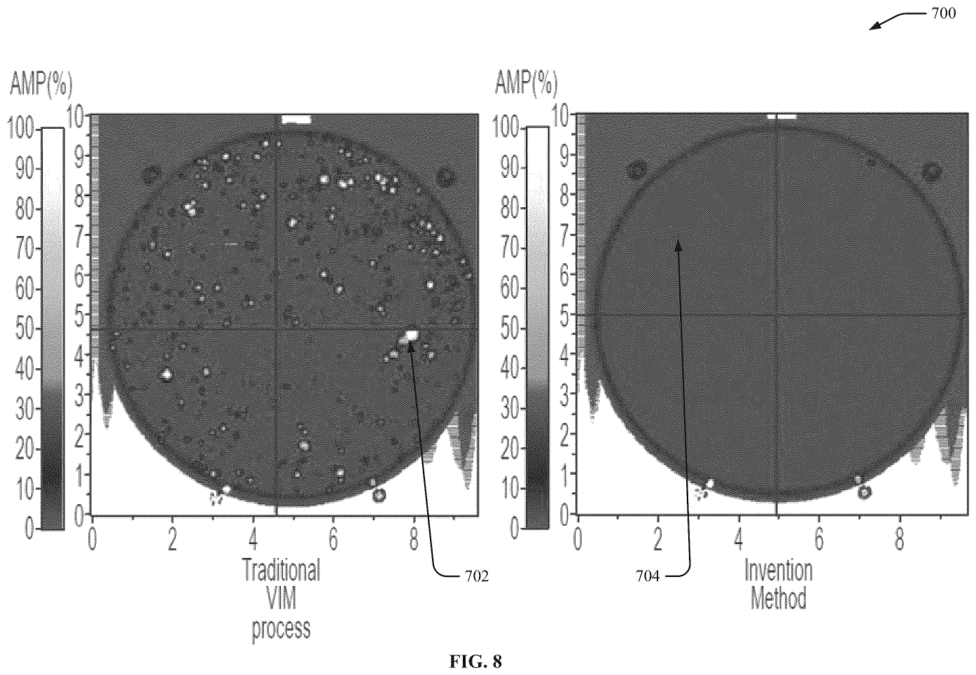

FIG. 8 further provides measurable improvements using the herein disclosed VIM method compared to the traditional VIM process. FIG. 8 illustrates an ultrasonic scan visual comparison between the traditional VIM process compared to the disclosed VIM method. Improvements using the disclosed VIM method is evaluated utilizing the ultrasonic defect inspection described in U.S. Pat. No. 6,739,196. FIG. 8 presents a visual comparison map from the ultrasonic through-thickness test. The amplitude (AMP) represents the percentage of signal and the higher the amplitude the greater the defect. As illustrated, the traditional VIM process has many more signals with a higher AMP (%) compared to the disclosed VIM method. For example, the signal 702 has a higher amplitude than the signal 704. The disclosed VIM method produces a measurable reduction in defect level of about 50% or greater in comparison with the traditional VIM process. It is unexpected that the addition of the carbon getters into the melt in accordance with the disclosed VIM method results in a measureable reduction in defect level of the ingot 100, when compared with the traditional VIM process. As was stated above, a reduction in the defect level of the ingot 100 naturally results in a reduction in the defect level of the sputtering target 130 that is produced using the ingot 100.

What has been described above includes examples of the present specification. It is, of course, not possible to describe every conceivable combination of components or methodologies for purposes of describing the present specification, but one of ordinary skill in the art may recognize that many further combinations and permutations of the present specification are possible. Each of the components or methodologies described above may be combined or added together in any permutation. Accordingly, the present specification is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A method of forming a low carbon defect copper-manganese (CuMn) sputtering target comprises:
selecting raw material comprising of copper (Cu) with a purity of at least about 99.9999% and an alloy addition, the alloy addition comprising:
manganese (Mn) with a purity of about 99.9% to about 99.999%, and one or more active elements; and
the one or more active elements including one or more of oxygen (O) at about 100 parts per million (ppm) to about 4000 ppm, iron (Fe) at about 5 parts per billion (ppb) to about 100 ppm, sulfur(S) at about 5 ppm to about 400 ppm, hydrogen (H) at about 1 ppm to about 10 ppm, and chromium (Cr) at about 5 ppb to about 200 ppm, wherein the manganese has a compositional range of up to about 5 wt %;
melting the raw material into a molten alloy;
casting the molten alloy into an ingot;
thermomechanical processing the ingot into a target blank; and
assembling the target blank into a sputtering target by joining the target blank onto a backing plate.

2. The method of claim 1, further comprising charging the alloy addition and the Cu into a crucible.

3. The method of claim 1, further comprising adding the alloy addition as a late addition by a dissolution device into a molten Cu, thereby forming the molten alloy.

4. The method of claim 3, further comprising dispensing, by the dissolution device, the alloy addition into a stirring wake of the molten Cu.

5. The method of claim 4, wherein the dispensing of the alloy addition is at a dissolution rate of about 17 grams/second (g/s) to about 167 g/s.

6. The method of claim 1, further comprising homogenizing a resulting molten bath of the Cu and the alloy addition for about 30 minutes (min) to about 120 min.
